(19) United States
(12) Patent Application Publication
(10) Pub. No.: US 2024/0313070 A1
(43) Pub. Date: Sep. 19, 2024

(54) METHOD AND STRUCTURE OF ACCURATELY CONTROLLING CONTACT GOUGING POSITION

(71) Applicant: INTERNATIONAL BUSINESS MACHINES CORPORATION, ARMONK, NY (US)

(72) Inventors: Ruilong Xie, Niskayuna, NY (US); Chanro Park, Clifton Park, NY (US); Min Gyu Sung, Latham, NY (US); Julien Frougier, Albany, NY (US); Juntao Li, Cohoes, NY (US)

(21) Appl. No.: 18/183,189

(22) Filed: Mar. 14, 2023

(51) Int. Cl. H01L 29/417; H01L 27/092; H01L 29/06; H01L 29/66; H01L 29/775; H01L 29/786

(52) U.S. Cl. CPC H01L 29/41733; H01L 27/0922; H01L 29/0673; H01L 29/66545; H01L 29/775; H01L 29/78696

(57) ABSTRACT

A microelectronic device including a nanosheet transistor that includes a source/drain. At least a first and a second dielectric shoulders located on top of the source/drain and the at least the first and second dielectric shoulders are located at a permitter of the source/drain. The source/drain includes a gouged area located at a center of the source/drain. A source/drain contact connected to the source/drain, where the source/drain contact is in contact with a top surface the first dielectric shoulder. The source/drain contact includes a protrusion that extends into the source/drain, and the source/drain contact protrusion is located within the gouged area of the source/drain.

### BACKGROUND

The present invention generally relates to the field of microelectronics, and more particularly to formation of gouges in the source/drain for the formation of contacts.

Nanosheet is the lead device architecture in continuing CMOS scaling. However, nanosheet technology has shown issues when scaling down such that as the devices become smaller and closer together, they are interfering with each other. With the number of devices being fit in a smaller area it is becoming harder to form a contact with enough surface interaction with the source/drain.

### BRIEF SUMMARY

Additional aspects and/or advantages will be set forth in part in the description which follows and, in part, will be apparent from the description, or may be learned by practice of the invention.

A microelectronic device including a nanosheet transistor that includes a source/drain. At least a first and a second dielectric shoulders located on top of the source/drain and the at least the first and second dielectric shoulders are located at a permitter of the source/drain. The source/drain includes a gouged area located at a center of the source/drain. A source/drain contact connected to the source/drain, where the source/drain contact is in contact with a top surface the first dielectric shoulder. The source/drain contact includes a protrusion that extends into the source/drain, and the source/drain contact protrusion is located within the gouged area of the source/drain.

A microelectronic device including a nanosheet transistor that includes a source/drain. At least a first and a second dielectric shoulders located on top of the source/drain. The at least the first and second dielectric shoulders are located at a permitter of the source/drain and the source/drain includes a gouged area located at a center of the source/drain. A source/drain contact connected to the source/drain and the source/drain contact is in contact with a top surface the first dielectric shoulder. The source/drain contact is prevented from being in contact with a top surface of the second dielectric shoulder and the source/drain contact includes a protrusion that extends into the source/drain. The source/drain contact protrusion is located within the gouged area of the source/drain.

A microelectronic device including a first nanosheet transistor that includes a first source/drain. A second nanosheet transistor that includes a second/drain. At least a first and a second dielectric shoulders located on top of the first source/drain. The at least the first and second dielectric shoulders are located at a permitter of the first source/drain and the first source/drain includes a gouged area located at a center of the first source/drain. At least a third and a fourth dielectric shoulders located on top of the second source/drain. The at least the third and fourth dielectric shoulders are located at a permitter of the second source/drain and the second source/drain includes a gouged area located at a center of the second source/drain. A first source/drain contact connected to the first source/drain. The first source/drain contact is in contact with a top surface the first dielectric shoulder and a top surface of the second dielectric shoulder. The first source/drain contact includes a first protrusion that extends into the first source/drain and the first source/drain contact protrusion is located within the gouged area of the first source/drain. A second source/drain contact connected to the second source/drain. The second source/drain contact is in contact with a top surface the third dielectric shoulder and the second source/drain contact is prevent from being in contact with a top surface of the fourth dielectric shoulder. The second source/drain contact includes a second protrusion that extends into the second source/drain and the second source/drain contact protrusion is located within the gouged area of the second source/drain.

### BRIEF DESCRIPTION OF THE DRAWINGS

The above and other aspects, features, and advantages of certain exemplary embodiments of the present invention will be more apparent from the following description taken in conjunction with the accompanying drawings, in which:

FIG. 1 illustrates a top-down view of multiple nano devices or transistors, in accordance with the embodiment of the present invention.

FIG. 2 illustrates a cross section X of the nano stack after the formation of the source/drain, the source/drains, in accordance with the embodiment of the present invention.

FIG. 3 illustrates a cross section Y of the source/drain region after the formation of the source/drains, in accordance with the embodiment of the present invention.

FIG. 4 illustrates a cross section X of the nano stack after the formation of a first dielectric liner, the source/drains, in accordance with the embodiment of the present invention.

FIG. 5 illustrates a cross section Y of the source/drain region after the formation of a first dielectric liner, in accordance with the embodiment of the present invention.

FIG. 6 illustrates a cross section X of the nano stack after the formation of a dielectric shoulders, in accordance with the embodiment of the present invention.

FIG. 7 illustrates a cross section Y of the source/drain region after the formation of a dielectric shoulders, in accordance with the embodiment of the present invention.

FIG. 8 illustrates a cross section X of the nano stack after the formation of a second dielectric liner and an oxide layer, in accordance with the embodiment of the present invention.

FIG. 9 illustrates a cross section Y of the source/drain region after the formation of a second dielectric liner and an oxide layer, in accordance with the embodiment of the present invention.

FIG. 10 illustrates a cross section X of the nano stack after the removal of the dummy gate and the plurality of sacrificial layers, in accordance with the embodiment of the present invention.

FIG. 11 illustrates a cross section Y of the source/drain region after the removal of the dummy gate and the plurality of sacrificial layers, in accordance with the embodiment of the present invention.

FIG. 12 illustrates a cross section X of the nano stack after the formation of the gate, in accordance with the embodiment of the present invention.

FIG. 13 illustrates a cross section Y of the source/drain region after the formation of the gate, in accordance with the embodiment of the present invention.

FIG. 14 illustrates a cross section X of the nano stack after the formation of the gate cut, in accordance with the embodiment of the present invention.

FIG. 15 illustrates a cross section Y of the source/drain region after the formation of the gate cut, in accordance with the embodiment of the present invention.

FIG. 16 illustrates a cross section X of the nano stack after the formation of an interlayer dielectric layer, in accordance with the embodiment of the present invention.

FIG. 17 illustrates a cross section Y of the source/drain region after the formation of an interlayer dielectric layer, in accordance with the embodiment of the present invention.

FIG. 18 illustrates a cross section X of the nano stack after the contact patterning, in accordance with the embodiment of the present invention.

FIG. 19 illustrates a cross section Y of the source/drain region after the contact patterning, in accordance with the embodiment of the present invention.

FIG. 20 illustrates a cross section X of the nano stack after the gouging process, in accordance with the embodiment of the present invention.

FIG. 21 illustrates a cross section Y of the source/drain region after the gouging process, in accordance with the embodiment of the present invention.

FIG. 22 illustrates a cross section X of the nano stack after the formation of the contacts, in accordance with the embodiment of the present invention.

FIG. 23 illustrates a cross section Y of the source/drain region after the formation of the contacts, in accordance with the embodiment of the present invention.

FIG. 24 illustrates a cross section X of the nano stack after the formation of the back-end-of-the-line layers, in accordance with the embodiment of the present invention.

FIG. 25 illustrates a cross section Y of the source/drain region after the formation of the back-end-of-the-line layers, in accordance with the embodiment of the present invention.

FIG. 26 illustrates a cross section X of the nano stack after the formation of the back-end-of-the-line layers for an alternative structure of the contacts, in accordance with the embodiment of the present invention.

FIG. 27 illustrates a cross section Y of the source/drain region after the formation of the back-end-of-the-line layers for an alternative structure of the contacts, in accordance with the embodiment of the present invention.

### DETAILED DESCRIPTION

The following description with reference to the accompanying drawings is provided to assist in a comprehensive understanding of exemplary embodiments of the invention as defined by the claims and their equivalents. It includes various specific details to assist in that understanding but these are to be regarded as merely exemplary. Accordingly, those of ordinary skill in the art will recognize that various changes and modifications of the embodiments described herein can be made without departing from the scope and spirit of the invention. In addition, descriptions of well-known functions and constructions may be omitted for clarity and conciseness.

The terms and the words used in the following description and the claims are not limited to the bibliographical meanings but are merely used to enable a clear and consistent understanding of the invention. Accordingly, it should be apparent to those skilled in the art that the following description of exemplary embodiments of the present invention is provided for illustration purpose only and not for the purpose of limiting the invention as defined by the appended claims and their equivalents.

It is understood that the singular forms “a,” “an,” and “the” include plural referents unless the context clearly dictates otherwise. Thus, for example, reference to “a component surface” includes reference to one or more of such surfaces unless the context clearly dictates otherwise.

Detailed embodiments of the claimed structures and the methods are disclosed herein: however, it can be understood that the disclosed embodiments are merely illustrative of the claimed structures and methods that may be embodied in various forms. This invention may, however, be embodied in many different forms and should not be construed as limited to the exemplary embodiments set forth herein. Rather, these exemplary embodiments are provided so that this disclosure will be thorough and complete and will fully convey the scope of this invention to those skilled in the art. In the description, details of well-known features and techniques may be omitted to avoid unnecessarily obscuring the present embodiments.

References in the specification to “one embodiment,” “an embodiment,” an example embodiment,” etc., indicate that the embodiment described may include a particular feature, structure, or characteristic, but every embodiment may not include the particular feature, structure, or characteristic. Moreover, such phrases are not necessarily referring to the same embodiment. Further, when a particular feature, structure, or characteristic is described in connection with an embodiment, it is submitted that it is within the knowledge of one of ordinary skill in the art o affect such feature, structure, or characteristic in connection with other embodiments whether or not explicitly described.

For purpose of the description hereinafter, the terms “upper,” “lower,” “right,” “left,” “vertical,” “horizontal,” “top,” “bottom,” and derivatives thereof shall relate to the disclosed structures and methods, as orientated in the drawing figures. The terms “overlying,” “atop,” “on top,” “positioned on,” or “positioned atop” mean that a first element, such as a first structure, is present on a second element, such as a second structure, where intervening elements, such as an interface structure may be present between the first element and the second element. The term “direct contact” means that a first element, such as a first structure, and a second element, such as a second structure, are connected without any intermediary conducting, insulating, or semiconductor layer at the interface of the two elements.

In the interest of not obscuring the presentation of embodiments of the present invention, in the following detailed description, some processing steps or operations that are known in the art may have been combined together for presentation and for illustrative purposes and in some instance may have not been described in detail. In other instances, some processing steps or operations that are known in the art may not be described at all. It should be understood that the following description is rather focused on the distinctive features or elements of various embodiments of the present invention.

Various embodiments of the present invention are described herein with reference to the related drawings. Alternative embodiments can be devised without departing from the scope of this invention. It is noted that various connections and positional relationships (e.g., over, below, adjacent, etc.) are set forth between elements in the following description and in the drawings. These connections and/or positional relationships, unless specified otherwise, can be direct or indirect, and the present invention is not intended to be limiting in this respect. Accordingly, a coupling of entities can refer to either a direct or indirect coupling, and a positional relationship between entities can be direct or indirect positional relationship. As an example of indirect positional relationship, references in the present description to forming layer “A” over layer “B” includes situations in which one or more intermediate layers (e.g., layer “C”) is between layer “A” and layer “B” as long as the relevant characteristics and functionalities of layer “A” and layer “B” are not substantially changed by the intermediate layer(s).

The following definitions and abbreviations are to be used for the interpretation of the claims and the specification. As used herein, the terms “comprises,” “comprising,” “includes,” “including,” “has,” “having,” “contains,” or “containing” or any other variation thereof, are intended to cover a non-exclusive inclusion. For example, a composition, a mixture, process, method, article, or apparatus that comprises a list of elements is not necessarily limited to only those elements but can include other element not expressly listed or inherent to such composition, mixture, process, method, article, or apparatus.

Additionally, the term “exemplary” is used herein to mean “serving as an example, instance or illustration.” Any embodiment or design described herein as “exemplary” is not necessarily to be construed as preferred or advantageous over other embodiment or designs. The terms “at least one” and “one or more” can be understood to include any integer number greater than or equal to one, i.e., one, two, three, four, etc. The terms “a plurality” can be understood to include any integer number greater than or equal to two, i.e., two, three, four, five, etc. The term “connection” can include both indirect “connection” and a direct “connection.”

As used herein, the term “about” modifying the quantity of an ingredient, component, or reactant of the invention employed refers to variation in the numerical quantity that can occur, for example, through typical measuring and liquid handling procedures used for making concentrations or solutions. Furthermore, variation can occur from inadvertent error in measuring procedures, differences in manufacture, source, or purity of the ingredients employed to make the compositions or carry out the methods, and the like. The terms “about” or “substantially” are intended to include the degree of error associated with measurement of the particular quantity based upon the equipment available at the time of the filing of the application. For example, about can include a range of ±8%, or 5%, or 2% of a given value. In another aspect, the term “about” means within 5% of the reported numerical value. In another aspect, the term “about” means within 10, 9, 8, 7, 6, 5, 4, 3, 2, or 1% of the reported numerical value.

Various processes are used to form a micro-chip that will packaged into an integrated circuit (IC) fall in four general categories, namely, film deposition, removal/etching, semiconductor doping and patterning/lithography. Deposition is any process that grows, coats, or otherwise transfers a material onto the wafer. Available technologies include physical vapor deposition (PVD), chemical vapor deposition (CVD), electrochemical deposition (ECD), molecular beam epitaxy (MBE), and more recently, atomic layer deposition (ALD) among others. Removal/etching is any process that removes material from the wafer. Examples include etching process (either wet or dry), reactive ion etching (RIE), and chemical-mechanical planarization (CMP), and the like. Semiconductor doping is the modification of electrical properties by doping, for example, transistor sources and drains, generally by diffusion and/or by ion implantation. These doping processes are followed by furnace annealing or by rapid thermal annealing (RTA). Annealing serves to activate the implant dopants. Films of both conductors (e.g., aluminum, copper, etc.) and insulators (e.g., various forms of silicon dioxide, silicon nitride, etc.) are used to connect and isolate electrical components. Selective doping of various regions of the semiconductor substrate allows the conductivity of the substrate to be changed with the application of voltage.

Reference will now be made in detail to the embodiments of the present invention, examples of which are illustrated in the accompanying drawings, where like reference numerals refer to like elements throughout. The present invention is directed towards forming a gouge in the source/drain, more specifically, ensuring that the gouge will be formed in the center of the source/drain. When the gouge is not formed in the center of the source/drain, it causes the formation of sections of the source/drain that have narrow widths that causes an increase of the resistance at these locations. By forming the gouge in the center of the source/drain prevents the creation of narrow/small source/drain sections that have a high resistance to be created. The centering of the gouge is accomplished by forming a pair of shoulder/spacers on top of the source/drain prior to the gouging process. The shoulders act as a guide for the gouging process, and the shoulders ensure that there will be enough source/drain material located beneath the shoulder to prevent the formation of high resistance areas sin the source/drain.

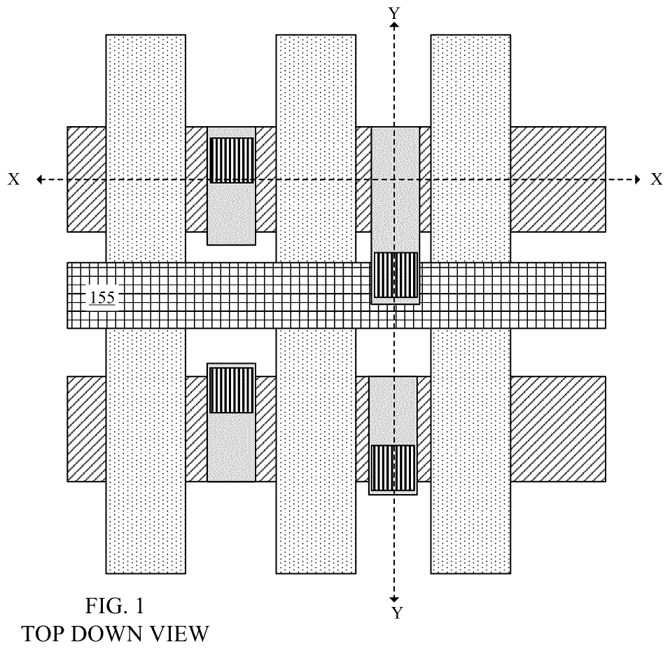

FIG. 1 illustrates a top-down view of multiple devices, in accordance with the embodiment of the present invention. The cross-section X extends horizontally through the nano devices, nano stacks, nanosheet transistors, or transistors of one of the devices. Cross section Y is perpendicular to cross section X, where cross section Y is through a source/drain region that spans across multiple nano stacks.

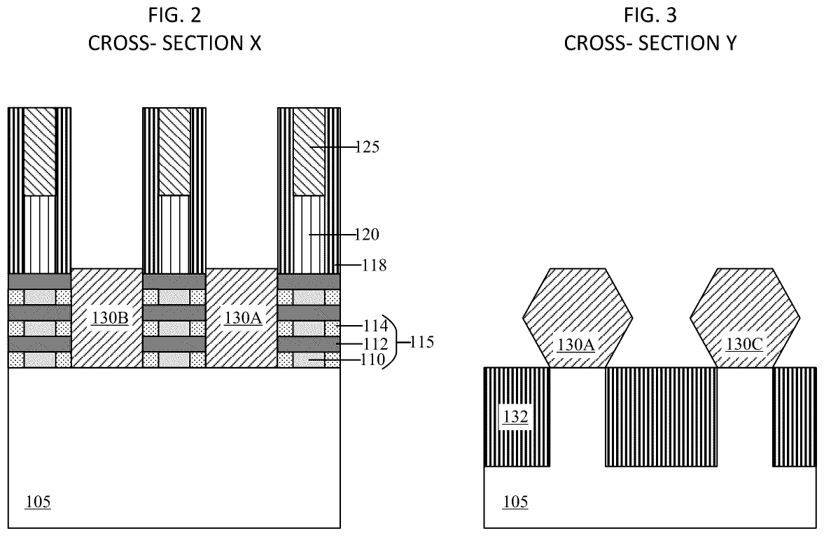

Referring now to FIGS. 2, and 3, illustrate a structure during an intermediate step of a method of fabricating a nanosheet transistor structure according to an embodiment of the invention. FIGS. 2, and 3 illustrate the processing stage after the formation of the source/drains. FIG. 2 illustrates a substrate 105, a plurality of nano stacks 115, a dummy gate 120, an upper spacer 118, a first source/drain 130A, a second source/drain 130B, and a hardmask 125.

The substrate 105 can be, for example, a material including, but not necessarily limited to, silicon (Si), silicon germanium (SiGe), Si:C (carbon doped silicon), carbon doped silicon germanium (SiGe:C), III-V, II-V compound semiconductor or another like semiconductor. In addition, multiple layers of the semiconductor materials can be used as the semiconductor material of the substrate 105. In some embodiments, substrate 105 includes both semiconductor materials and dielectric materials. The semiconductor substrate 105 may also comprise an organic semiconductor or a layered semiconductor such as, for example, Si/SiGe, a silicon-on-insulator or a SiGe-on-insulator. A portion or the entire semiconductor substrate 105 may also be comprised of an amorphous, polycrystalline, or monocrystalline. The semiconductor substrate 105 may be doped, undoped or contain doped regions and undoped regions therein.

The nano stacks 115 includes a plurality of channel layers 112 (e.g., Si nano sheets), a plurality of sacrificial layers 110, and an inner spacer 114. The channel layers 112 are spaced apart from each other, such that an inner spacer 114 is located between the channel layers 112. The plurality of sacrificial layers 110 can be comprised of SiGe, where Ge is in the range of about 15% to 35%. The plurality of channel layers 112 can be comprised of, for example, Si. The inner spacer 114 and the upper spacer 118 can be comprised of, for example, a nitride-based spacer material. The source/drains 130A, and 130B are located between nano stack columns as illustrated in FIG. 2. FIG. 3 illustrates cross section Y showing a source/drain region that includes the first source/drain 130A, and a third source/drain 130C. A shallow trench isolation layer 132 is located in the trenches that were formed in the substrate 105 during nano column formation process.

The first source/drain 130A, the second source/drain 130B, and the third source/drain 130C, can be for example, a n-type epitaxy, or a p-type epitaxy. For n-type epitaxy, an n-type dopant selected from a group of phosphorus (P), arsenic (As) and/or antimony (Sb) can be used. For p-type epitaxy, a p-type dopant selected from a group of boron (B), gallium (Ga), indium (In), and/or thallium (Tl) can be used. Other doping techniques such as ion implantation, gas phase doping, plasma doping, plasma immersion ion implantation, cluster doping, infusion doping, liquid phase doping, solid phase doping, and/or any suitable combination of those techniques can be used. In some embodiments, dopants are activated by thermal annealing such as laser annealing, flash annealing, rapid thermal annealing (RTA) or any suitable combination of those techniques.

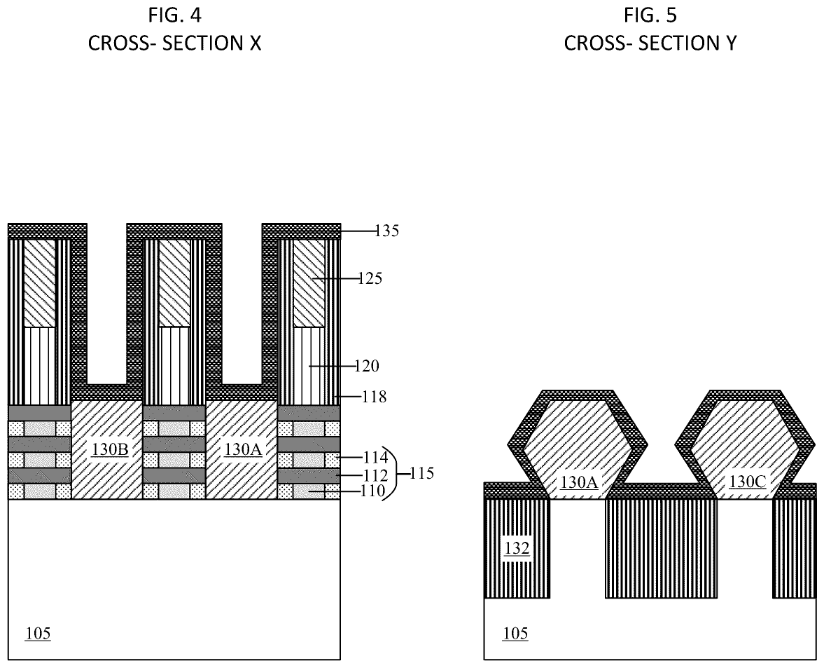

FIGS. 4, and 5 illustrate the processing stage after the formation of a first dielectric liner 135. A first dielectric liner 135 is formed on the exposed surfaces, such that the first dielectric liner 135 is located on top of the source/drains 130A, 130B, 130C, the hardmask 125, the shallow trench isolation layer 132. The first dielectric liner 135 can be comprised of, for example, AlOₓ, AlNₓ, HfO₂, SiC or a similar material. The shoulders will be formed out of the first dielectric liner 135, which will be described in further detail below.

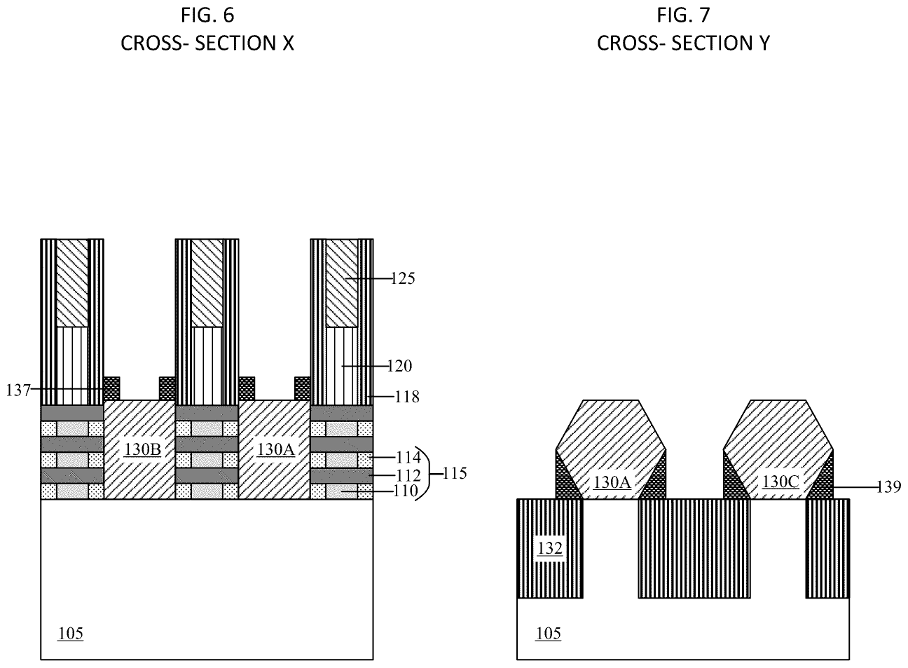

FIGS. 6, and 7 illustrate the processing stage after the formation of a dielectric shoulders 137. The first dielectric liner 135 is etched/pulled down by, for example, a reactive ion etching process, to form the dielectric shoulders 137. The dielectric shoulders 137 are located on top of the first source/drain 130A and the second source/drain 130B, more specifically, the dielectric shoulders 137 are located at the boundary of the source/drain 130A, 130B, 130C and the upper spacer 118. For example, the dielectric shoulders 137 are in contact with a top surface of the first source/drain 130A and a side surface of the upper spacer 118. The dielectric shoulders 137 cover a portion of the top surface of the source/drains 130A, 130B, 130C, while leaving other portions exposed. A center portion of the top surface of the source/drains 130A, 130B, 130C remains exposed, since the dielectric shoulders 137 are located at the perimeter of the source/drain 130A, 130B, 130C, and the dielectric shoulders 137 are located adjacent to the upper spacer 118. After the etching process, a portion 139 of the first dielectric liner 135 remains located beneath the source/drain 130A, 130B, 130C, as illustrate in FIG. 7.

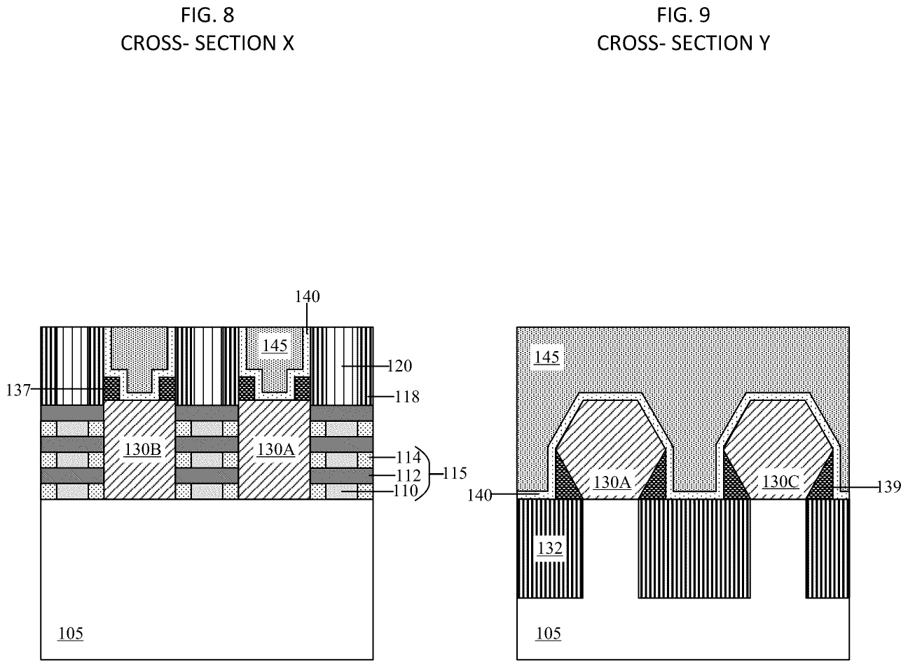

FIGS. 8, and 9 illustrate the processing stage after the formation of a second dielectric liner 140 and an oxide layer 145. A second dielectric liner 140 is formed on the exposed surfaces such that the second dielectric liner 140 is located on top of the dielectric shoulder 137, the source/drains 130A, 130B, 130C, the shallow trench isolation layer 132, and the remaining portion 139 of the first dielectric liner 135. The second dielectric liner 140 can be comprised of, for example, a nitride-based material, such as SiN. An oxide layer 145 is formed on top of the second dielectric liner 140, where the oxide layer 145 can be comprised of, for example, SiO₂. The excess second dielectric liner 140, the oxide layer 145, and the hardmask 125 are removed by, for example, chemical mechanical processing (CMP) to create a flush top surface while removing excess materials.

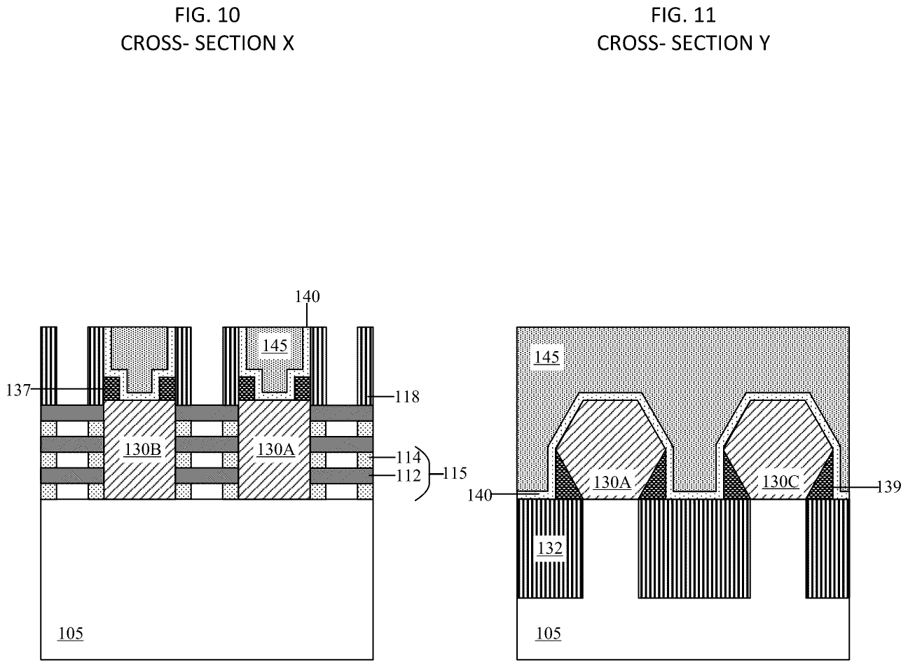

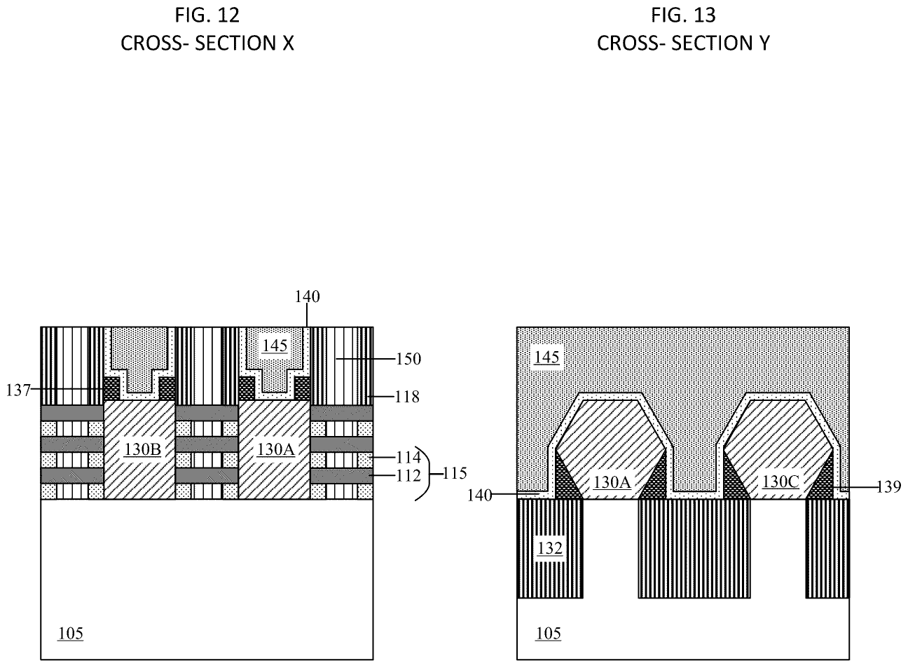

FIGS. 10, and 11 illustrate the processing stage after the removal of the dummy gate 120 and the plurality of sacrificial layers 110. The dummy gate 120 and the plurality of sacrificial layers 110 are removed to create space for the formation of the gate 150. FIGS. 12, and 13 illustrate the processing stage after the formation of the gate 150. The gate 150 is formed in the empty locations created by the removal of the dummy gate 120 and the plurality of sacrificial layers 110. The gate 150 is wrapped around each of the channel layers 112 and located between segments of the upper spacer 118. The gate 150 can be comprised of, for example, a gate dielectric liner, such as high-k dielectric like HfO₂, ZrO₂, HfLₐOₓ, etc., and work function layers, such as TiN, TiAlC, TiC, etc., and conductive metal fills, like W.

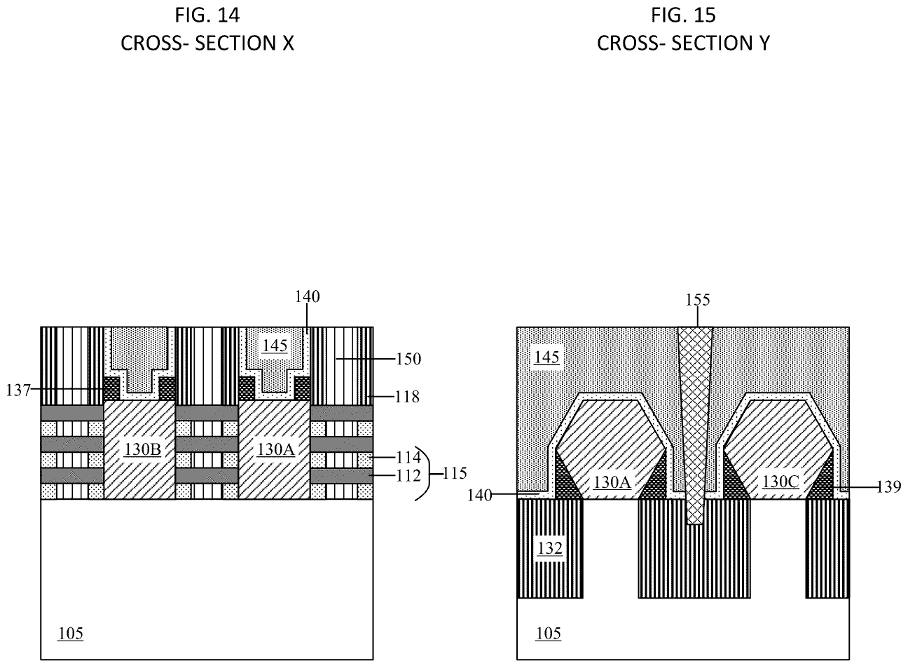

FIGS. 14, and 15 illustrate the processing stage after the formation of the gate cut 155. A trench (not shown) is formed in the space between the nano devices/nano sheet transistors and the trench is filled with a dielectric material to form gate cut 155. The gate cut 155 is comprised of nitride-based dielectric material.

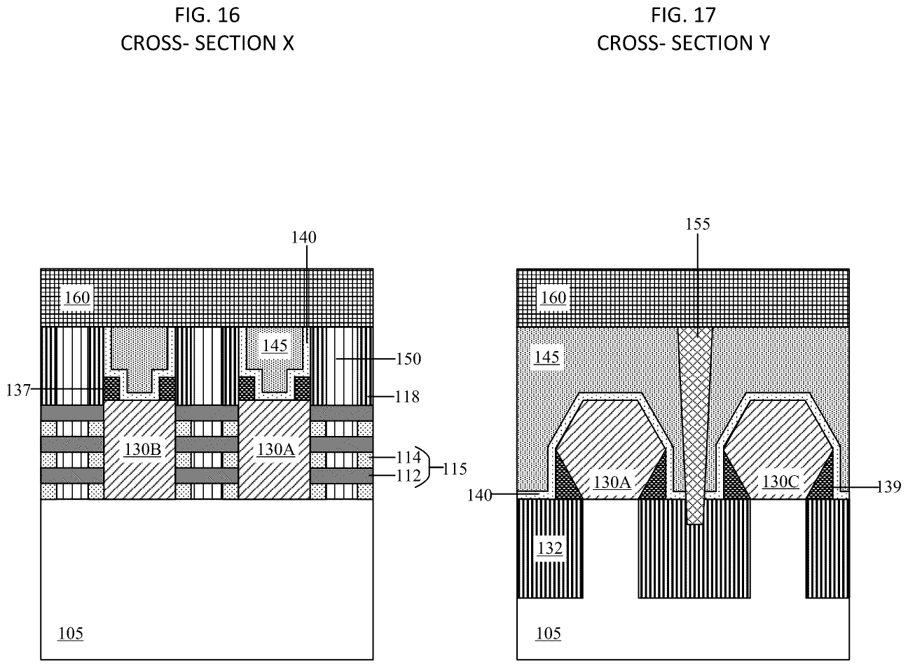

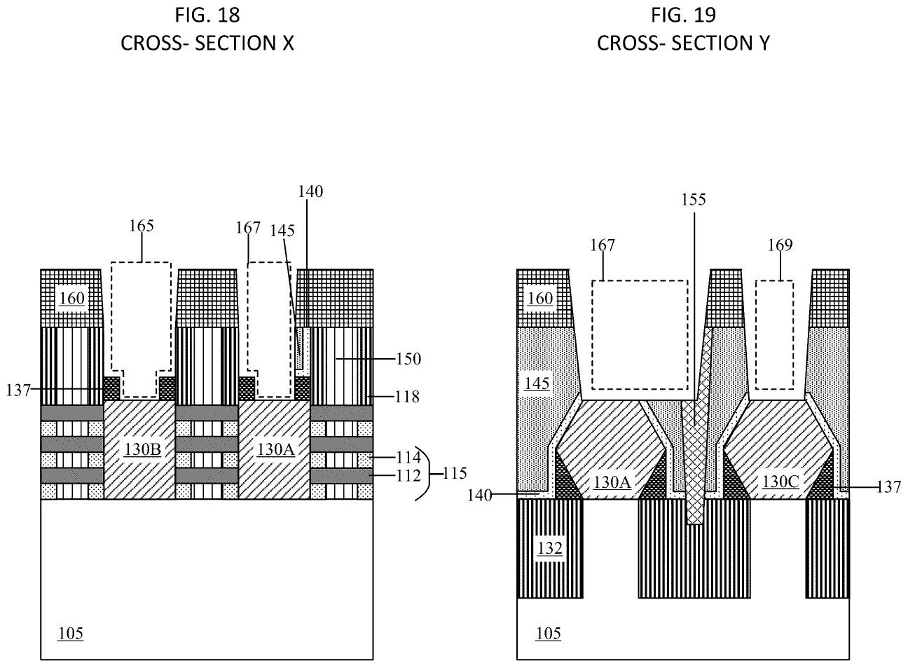

FIGS. 16, and 17 illustrate the processing stage after the formation of the interlayer dielectric layer 160 and FIGS. 18 and 19 illustrate the processing stage after the contact patterning. An interlayer dielectric layer 160 is formed on top of the exposed surfaces of the gate 150, the upper spacer 118, and the oxide layer 145. The interlayer dielectric layer 160, the oxide layer 145, the second dielectric liner 140, and the gate cut 155 are patterned/etched to form a plurality of trenches 165, 167, and 169. The plurality of trenches 165, 167, and 169 represent a plurality of different outcomes/scenarios of the etching process. The outcome/scenario of the etching process can result in one type of scenario or multiple types of scenarios occurring. The first trench 165 represents an aligned etching scenario, meaning that the second dielectric liner 140 and the oxide layer 145 located above the dielectric shoulders 137 and the second source/drain 130B is removed. The top surface and a side surface of multiple dielectric shoulders 137 and the top surface of the second source/drain 130B are exposed by the first trench 165. The second trench 167 represents a mis-aligned etching scenario. The mis-aligned etching scenario illustrates an outcome where a portion of the second dielectric liner 140 and a portion of the oxide layer 145 remains after the etching process. A portion of these layers (the second dielectric liner 140 and the oxide layer 145) remains located above one of the dielectric shoulders 137. In this miss-aligned scenario, one of the dielectric shoulders 137 has a top and side surface exposed, while another dielectric shoulder 137 has a side surface exposed while its top surface remains covered. The top surface of the first source/drain 130A is still exposed by the second trench 167 in the mis-aligned scenario. Furthermore, the second trench 167 can extend into the gate cut 155 as illustrated in FIG. 19. The third trench 169 can be either an aligned trench or another miss-aligned trench. The dielectric shoulders 137 in either scenario (aligned/mis-aligned) are important to ensure that the gouging process occurs at the expose center locations of the source/drains 130A, 130B, 130C, while the dielectric shoulders 137 prevent the gouging from occurring at a location that is too close to the sides of the source/drains 130A, 130B, 130C.

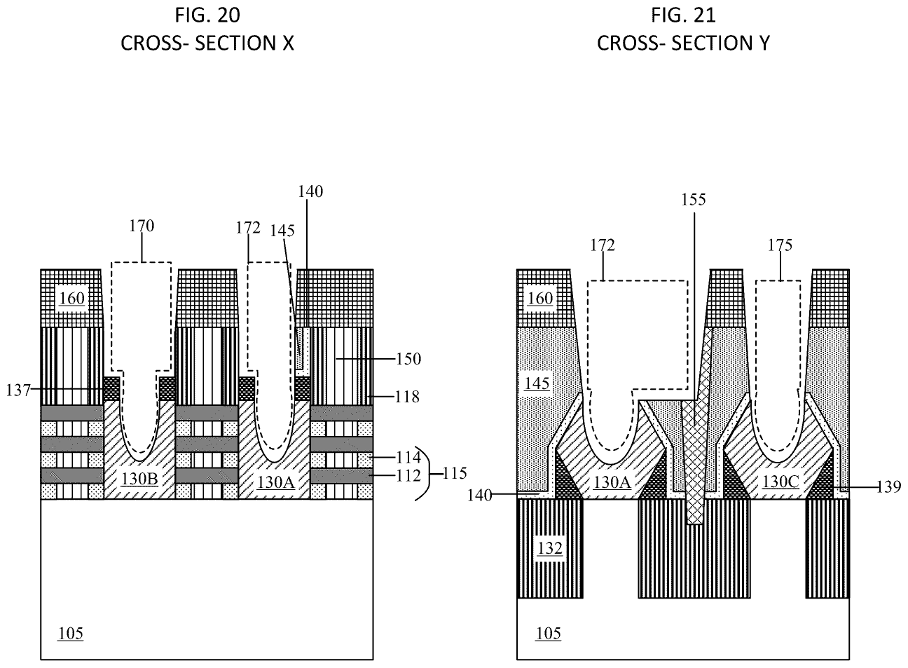

FIGS. 20 and 21 illustrate the processing stage after the gouging of the source/drains 130A, 130B, and 130C. The first, second, and third source/drains 130A, 130B, and 130C are gouged, i.e., a portion of the source/drains 130A, 130B, 130C are removed. The dielectric shoulders 137 act as a spacing element and a guide element to direct the gouging process towards the center areas of the source/drains 130A, 130B, 130C. The dielectric shoulders 137 prevents the gouging process from removing source/drain material located beneath the dielectric shoulders 137. Thus, enough source/drain material is present beneath the dielectric shoulders to prevent a formation of a high resistance area of the source/drain (e.g., an area with a small width). In the aligned scenario and the miss-aligned scenario a portion of the first source/drain 130A and second source/drain 130B is gouged/removed to create a first gouged trench 170 and a second gouged trench 172, respectively. The third gouged trench 175 is created by gouging out a portion of the third source/drain 130C.

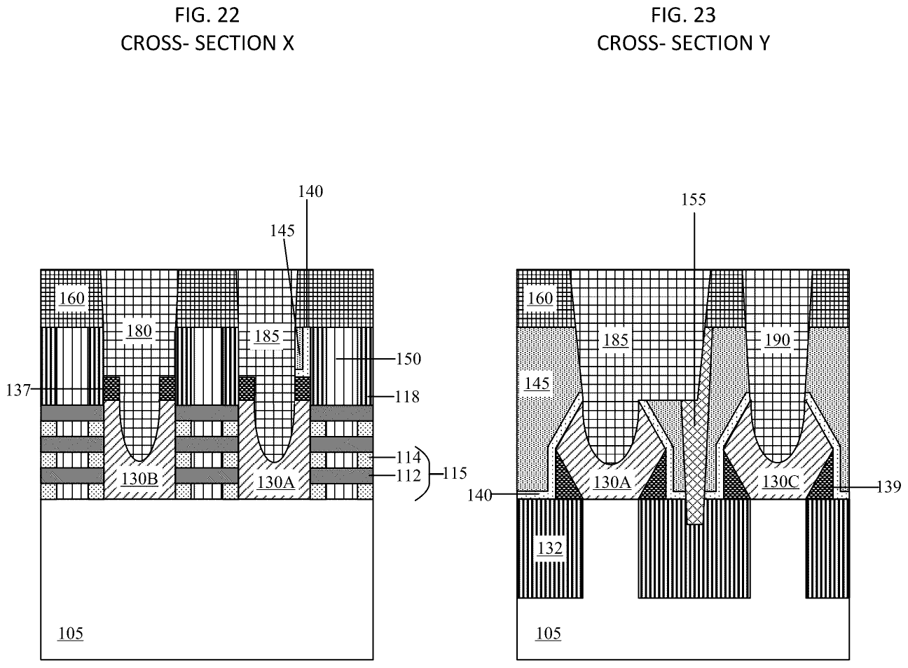

FIGS. 22 and 23 illustrate the processing stage after the formation of contacts 180, 185, and 190. The first, second and third gouged trenches 170, 172 and 175 are filled with a conductive material to form a first contact 180, a second contact 185, and a third contact 190. The gouging process allows for an increase in the available surface of the source/drains 130A, 130B, 130C, for contact/interacting with the contacts 180, 185, 190, respectively.

The first contact 180 shows the scenario where the first gouged trench 170 was correctly aligned. The first contact 180 has multiple steps that rest on top of the dielectric shoulders 137. The first contact 180 further includes a protrusion that is in contact with the side surfaces of the dielectric shoulders 137. The first contact 180 protrusion is located between at least two dielectric shoulders 137. The first contact 180 protrusion extends into the center of the second source/drain 130B and the first contact 180 protrusion is in contact with the second source/drain 130B. The second contact 185 shows the scenario where the second gouged trench 172 was miss-aligned. The second contact 185 is in contact with the second dielectric liner 140 and the oxide layer 145. The second contact 185 is contact with the top surface of one of the dielectric shoulders 137 but is prevent from contact the top surface of the other should because of the oxide layer 145 and the second dielectric liner 140. The second contact 185 further includes a protrusion that is in contact with the side surfaces of the dielectric shoulders 137. The second contact 185 protrusion extends into the center of the first source/drain 130A and the second contact 185 protrusion is in contact with the first source/drain 130A. FIG. 23 illustrates that the second contact 185 can extend horizontally into the gate cut 155. FIG. 23 illustrates that the second contact 185 (i.e., the mis-aligned scenario) extends into the gate cut 155, but the first contact 180 (i.e., the aligned scenario) could extend into the gate cut 155, or both contacts 180, 185 could extend into the gate cut 155. FIG. 23 further illustrates the third contact 190 extending into the third source/drain 130C.

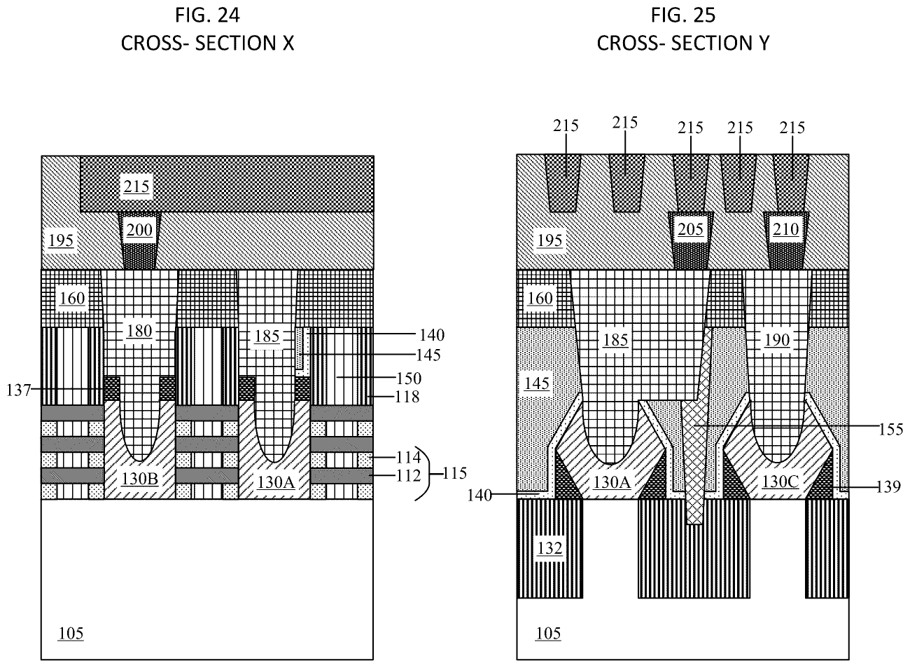

FIGS. 24 and 25 illustrate the processing stage after the formation back-end-of-the-line layers. The back-end-of-the-line (BEOL) layers can include a BEOL interlayer dielectric layer 195, a plurality of contact vias 200, 205, and 210, and a plurality of metal lines 215. The BEOL interlayer dielectric layer 195 is formed on top of the interlayer dielectric layer 160, the first contact 180, the second contact 185, and the third contact 185. Trenches (not shown) are formed in the BEOL interlayer dielectric layer 195 and filled with a conductive metal to form a plurality of contact vias 200, 205, 210 and a plurality of metal lines 215.

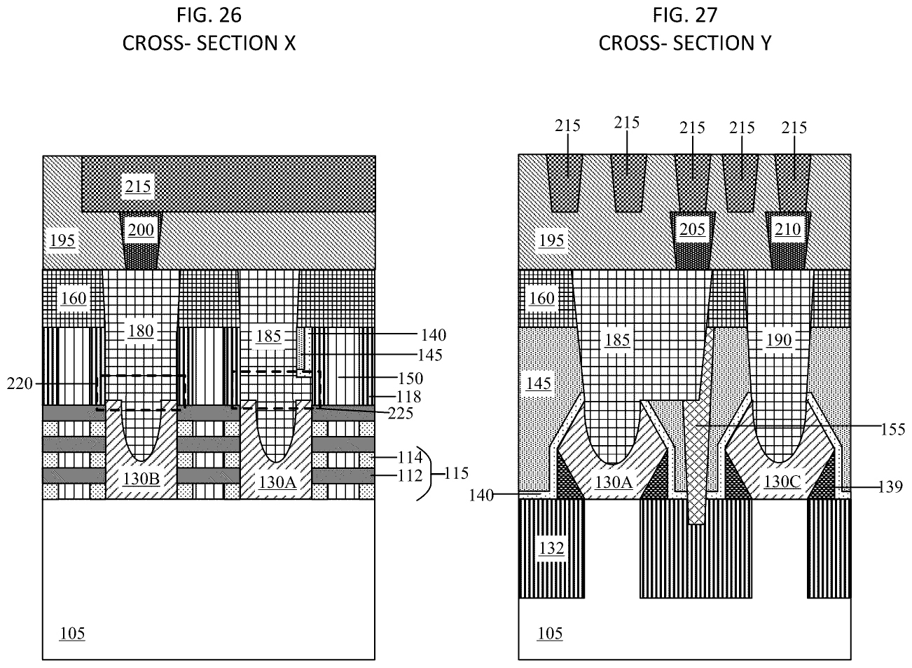

FIGS. 26 and 27 illustrate the processing stage after the formation back-end-of-the-line layers for an alternative formation of the contacts 180, 185, and 190. The alternative structure is achieved by the removal of the dielectric shoulders 137 after the gouging process but prior to the conductive metal fill. Dashed boxes 220 and 225 emphasize the structural differences between the contacts shown in FIG. 26 and the contact shown in FIG. 24. Dashed box 220 emphasizes that the first contact 180 is in direct contact with the top surface of the second source/drain 130B. Such that the steps of the first contact 180 that were located on top of dielectric shoulders 137 (as illustrated in FIG. 24) are now located directly on top of the second source/drain 130B.

Dashed box 225 emphasizes mis-aligned scenario, where that the second contact 185 is in direct contact with the top surface of the first source/drain 130A. Furthermore, the second contact 185 extends under the remaining layers of the oxide layer 145 and the second dielectric liner 140. Thus, the remaining layers of the oxide layer 145 and the second dielectric liner 140 are located horizontally between a segment of the upper spacer 118 and the second contact 185. Furthermore, the remaining layers of the oxide layer 145 and the second dielectric liner 140 are located vertically between the second contact 185 and the interlayer dielectric layer 160.

While the invention has been shown and described with reference to certain exemplary embodiments thereof, it will be understood by those skilled in the art that various changes in form and details may be made therein without departing from the spirit and scope of the present invention as defined by the appended claims and their equivalents.

The descriptions of the various embodiments of the present invention have been presented for purposes of illustration but are not intended to be exhaustive or limited to the embodiments disclosed. Many modifications and variations will be apparent to those of ordinary skill in the art without departing from the scope and spirit of the described embodiments. The terminology used herein was chosen to best explain the principles of the one or more embodiment, the practical application or technical improvement over technologies found in the marketplace, or to enable others of ordinary skill in the art to understand the embodiments disclosed herein.

What is claimed is:

1. A microelectronic device comprising:
a nanosheet transistor that includes a source/drain;
at least a first and a second dielectric shoulders located on top of the source/drain, wherein the at least the first and second dielectric shoulders are located at a permitter of the source/drain, wherein the source/drain includes a gouged area located at a center of the source/drain; and
a source/drain contact is connected to the source/drain, wherein the source/drain contact is in contact with a top surface the first dielectric shoulder, wherein the source/drain contact includes a protrusion that extends into the source/drain, wherein the source/drain contact protrusion is located within the gouged area of the source/drain.

2. The microelectronic device of claim 1, wherein the source/drain contact protrusion is located between the first dielectric shoulder and the second dielectric shoulder.

3. The microelectronic device of claim 2, wherein the source/drain contact protrusion is in contact with a side surface of the first dielectric shoulder.

4. The microelectronic device of claim 3, wherein the source/drain contact protrusion is in contact with a side surface of the second dielectric shoulder.

5. The microelectronic device of claim 4, wherein the contact is in contact with a top surface of the second dielectric shoulder.

6. The microelectronic device of claim 1, wherein a bottom surface of the first and second dielectric shoulders are in contact with a top surface of the source/drain.

7. The microelectronic device of claim 1, further comprising:
a dielectric gate cut located adjacent to the nanosheet transistor.

8. The microelectronic device of claim 7, wherein the contact extends into the gate cut.

9. A microelectronic device comprising:
a nanosheet transistor that includes a source/drain;
at least a first and a second dielectric shoulders located on top of the source/drain, wherein the at least the first and second dielectric shoulders are located at a permitter of the source/drain, wherein the source/drain includes a gouged area located at a center of the source/drain; and
a source/drain contact connected to the source/drain, wherein the source/drain contact is in contact with a top surface the first dielectric shoulder, wherein the source/drain contact is prevented from being in contact with a top surface of the second dielectric shoulder, wherein the source/drain contact includes a protrusion that extends into the source/drain, wherein the source/drain contact protrusion is located within the gouged area of the source/drain.

10. The microelectronic device of claim 9, wherein the source/drain contact protrusion is located between the first dielectric shoulder and the second dielectric shoulder.

11. The microelectronic device of claim 10, wherein the source/drain contact protrusion is in contact with a side surface of the first dielectric shoulder, wherein the source/drain contact protrusion is in contact with a side surface of the second dielectric shoulder.

12. The microelectronic device of claim 11, further comprising:
a dielectric liner located on top of the second dielectric shoulder; and
an oxide layer located on top of the dielectric liner.

13. The microelectronic device of claim 12, wherein the source/drain contact is connected to a side surface of the dielectric liner, and the source/drain contact is connected to a side surface of the oxide layer.

14. The microelectronic device of claim 9, wherein a bottom surface of the first and second dielectric shoulders are in contact with a top surface of the source/drain.

15. The microelectronic device of claim 9, further comprising:
a dielectric gate cut located adjacent to the nanosheet transistor.

16. The microelectronic device of claim 15, wherein the contact extends into the gate cut.

17. A microelectronic device comprising:
a first nanosheet transistor that includes a first source/drain;
a second nanosheet transistor that includes a second/drain;
at least a first and a second dielectric shoulders located on top of the first source/drain, wherein the at least the first and second dielectric shoulders are located at a permitter of the first source/drain, wherein the first source/drain includes a gouged area located at a center of the first source/drain;
at least a third and a fourth dielectric shoulders located on top of the second source/drain, wherein the at least the third and fourth dielectric shoulders are located at a permitter of the second source/drain, wherein the second source/drain includes a gouged area located at a center of the second source/drain;
a first source/drain contact connected to the first source/drain, wherein the first source/drain contact is in contact with a top surface the first dielectric shoulder and a top surface of the second dielectric shoulder, wherein the first source/drain contact includes a first protrusion that extends into the first source/drain, wherein the first source/drain contact protrusion is located within the gouged area of the first source/drain; and
a second source/drain contact connected to the second source/drain, wherein the second source/drain contact is in contact with a top surface the third dielectric shoulder, wherein the second source/drain contact is prevent from being in contact with a top surface of the fourth dielectric shoulder, wherein the second source/drain contact includes a second protrusion that extends into the second source/drain, wherein the second source/drain contact protrusion is located within the gouged area of the second source/drain.

18. The microelectronic device of claim 1, wherein the first source/drain contact protrusion is located between the first dielectric shoulder and the second dielectric shoulder, and wherein the second source/drain contact protrusion is located between the third dielectric shoulder and the fourth dielectric shoulder.

19. The microelectronic device of claim 18, further comprising:
a dielectric liner located on top of the fourth dielectric shoulder; and
an oxide layer located on top of the dielectric liner.

20. The microelectronic device of claim 19, wherein the second source/drain contact is connected to a side surface of the dielectric liner, and the second source/drain contact is connected to a side surface of the oxide layer.
